(19) United States
(12) Patent Application Publication
(10) Pub. No.: US 2025/0034713 A1
(43) Pub. Date: Jan. 30, 2025

(54) LIFT PINS, LIFT PIN ARRANGEMENTS AND SEMICONDUCTOR PROCESSING SYSTEMS WITH LIFT PIN ARRANGEMENTS, AND METHODS OF MAKING LIFT PIN ARRANGEMENTS FOR SEMICONDUCTOR PROCESSING SYSTEMS

(71) Applicant: ASM IP Holding B.V., Almere (NL)

(72) Inventor: Jaehyun Kim, Hwaseong-si (KR)

(21) Appl. No.: 18/782,336

(22) Filed: Jul. 24, 2024

Related U.S. Application Data
(60) Provisional application No. 63/529,478, filed on Jul. 28, 2023.

(51) Int. Cl. C23C 16/458

(52) U.S. Cl. CPC C23C 16/4585; C23C 16/4581

(57) ABSTRACT

A lift pin includes a lift pin body arranged along a lift pin axis having an enlarged contact pad, a stem segment extending axially from the contact pad, a neck segment extending axially from the stem segment and separated from the contact pad by the stem segment of the lift pin body, and a base segment extending axially from the neck segment and separated from the stem segment by the neck segment. The base segment of the lift pin body has a base segment width, the neck segment of the lift pin body has a neck segment width, and the neck segment width is smaller than the base segment width to carry a lift pin weight with the lift pin body. Lift pin arrangements, semiconductor processing systems including lift pin arrangements, and methods of making lift pin arrangements for semiconductor processing systems are also described.

### CROSS-REFERENCE TO RELATED APPLICATIONS

This application claims priority to U.S. Provisional Patent Application Ser. No. 63/529,478 filed Jul. 28, 2023 titled LIFT PINS, LIFT PIN ARRANGEMENTS AND SEMICONDUCTOR PROCESSING SYSTEMS WITH LIFT PIN ARRANGEMENTS, AND METHODS OF MAKING LIFT PIN ARRANGEMENTS FOR SEMICONDUCTOR PROCESSING SYSTEMS, the disclosure of which is hereby incorporated by reference in its entirety.

### FIELD OF INVENTION

The present disclosure generally relates to depositing material layer onto substrates. More particularly, the present disclosure relates to seating and unseating substrates from substrate supports prior to and subsequent to deposition of material layers onto substrates, such as during the deposition of material layers during the fabrication of semiconductor devices.

### BACKGROUND OF THE DISCLOSURE

Material layers are commonly deposited onto substrates during the fabrication of semiconductor devices, such as during the fabrication of logic and memory devices. Deposition is generally accomplished by seating the substrate on a substrate support within a reaction chamber, heating the substrate to a desired deposition temperature, and exposing the substrate to a material layer precursor under environmental conditions selected to cause a material layer to deposit onto the substrate. Once the material layer develops desired properties exposure of the substrate to the material layer precursor typically ceases, the substrate is unseated from the substrate support, and the substate removed from the reactor chamber to undergo further processing, as appropriate for the semiconductor device being fabrication. Seating may be accomplished using lift pins, which are generally slidably received within the substrate, and which slide through the substrate to seat and unseat the substrate from the substrate support.

One challenge to the use of lift pins for seating and unseating substrates within reaction chambers using lift pins is material accretion within mechanical clearances defined within the interior of the reaction chamber, such as between the lift pin and substrate support. For example, in some material layer deposition operations, material may accrete on the stem of the lift pin. The accreted material may be carried by the stem of the lift pin during movement of the lift pin through the substrate support, potentially increasing resistance to sliding movement of the lift pin through the substrate support and/or causing the lift pin to bind within the substrate support. Material may also accrete on the tips of the lift pins when seated on the substrate, increasing force that need be applied to the lift pin to initiate sliding of the lift pin through the substrate support to unseat the substrate from the substrate support once deposition of the material layer is complete. Moreover, static electricity and/or charges between the substrate support and the lift pins could prevent the lift pins from sliding through the substrate support.

Various countermeasures exist to limit lift pin binding within substrate supports. For example, the lift pin may be maintained at a temperature differing from that required for material layer deposition within the reaction chamber, limiting the tendency of material to accrete on the lift pin. The lift pin may be separated from the material layer precursor employed during the deposition process, for example by use of a bellows or providing a purge flow to the lift pin, also limiting the tendency of material to accrete on the lift pin during deposition of the material layer onto the substrate. And the interior of the reaction chamber may be etched subsequent to deposition of the material layer onto the substrate, removing accreted material prior to the accretion reaching size sufficient to cause the lift pin to bind within the substrate support. While generally satisfactory for their intended purpose, such countermeasures can add complexity to the reaction chamber architecture and/or increase cost of ownership of the reaction chamber due to increased usage of consumables and/or reduced reaction chamber throughput.

Such systems and methods have generally been satisfactory for their intended purpose. However, there remains a need for improved lift pins, lift pin arrangements and semiconductor processing systems, and methods of making lift pin arrangements for semiconductor processing systems. The present solution provides a solution this need.

### SUMMARY OF THE DISCLOSURE

A lift pin is provided. The lift pin includes a lift pin body arranged along a lift pin axis. The lift pin body has an enlarged contact pad, a stem segment, a neck segment, and a base segment. The stem segment of the lift pin extends axially from the contact pad. The neck segment of the lift pin body extends axially from the stem segment, is separated from the contact pad by the stem segment of the lift pin body and has a neck segment width. The base segment of the lift pin body extends axially from the neck segment, is separated from the stem segment by the neck segment and has a base segment width. The base segment width is greater than the neck segment width to carry a weight body with the lift pin body.

In addition to one or more of the features described above, or as an alternative, further examples of the lift pin may include that the lift pin body is formed from a ceramic material.

In addition to one or more of the features described above, or as an alternative, further examples of the lift pin may include that the contact pad has a contact pad width, that the stem segment has a stem segment width, and that the stem segment width is smaller than the contact pad width and greater than the neck segment width.

In addition to one or more of the features described above, or as an alternative, further examples of the lift pin may include that the base segment of the lift pin body has an annular seating face and a hemispherical portion. The annular seating face may extend about the neck segment of the lift pin body and oppose the stem segment of the lift pin body. The annular seating face may be orthogonal relative to the lift pin axis.

In addition to one or more of the features described above, or as an alternative, further examples of the lift pin may include that the base segment has base segment height, that the neck segment has a neck segment height that is greater than the base segment height, that the contact pad has a contact pad height that is greater than the neck segment height, and that the stem segment has a stem segment height that is greater than the contact pad height.

A lift pin arrangement is provided. The lift pin arrangement includes a lift pin as described above, a weight body, and a cap member. The weight body is seated on the base segment of the lift pin body and is axially fixed and radially free relative to the lift pin body. The cap member is slidably received on the lift pin body and extends circumferentially about the weight body. The cap member is further axially free and radially fixed relative to the lift pin body.

In addition to one or more of the features described above, or as an alternative, further examples of the lift pin arrangement may include that the lift pin body has a lift pin body center of gravity arranged along the lift pin axis, that the weight body has a weight body center of gravity radially offset from the lift pin axis, and that the cap member has a cap member center of gravity radially offset from the lift pin axis. The lift pin arrangement may have a lift pin arrangement center of gravity that is offset from the lift pin axis.

In addition to one or more of the features described above, or as an alternative, further examples of the lift pin arrangement may include that the weight body has a weight body width and a recess. The recess may have a recess depth that spans more than one-half of the weight body width of the weight body.

In addition to one or more of the features described above, or as an alternative, further examples of the lift pin arrangement may include that the weight body defines an interior shoulder facet that is substantially orthogonal relative to the lift pin axis. The weight body may have a C-shaped upper surface and a C-shaped lower surface axially opposite the C-shaped upper surface and is parallel with the interior shoulder facet. The interior shoulder facet may be axially spaced from the base segment of the lift pin body by a neck segment height of the neck segment.

In addition to one or more of the features described above, or as an alternative, further examples of the lift pin arrangement may include that the cap member has an axially extending key portion slidably received within the recess of the weight body.

In addition to one or more of the features described above, or as an alternative, further examples of the lift pin arrangement may include that the recess has a recess width, and that the neck segment width is substantially equivalent to the recess width.

In addition to one or more of the features described above, or as an alternative, further examples of the lift pin arrangement may include that the cap member has an annular upper surface and an annular lower surface. The annular upper surface of the cap body may extend circumferentially about the stem segment of the lift pin body and radially fix the cap member relative to the lift pin body. The annular lower surface of the cap member may extend about the weight body and radially fix the weight body relative to the cap member.

In addition to one or more of the features described above, or as an alternative, further examples of the lift pin arrangement may include that the lift pin body is formed from aluminum oxide (Al₂O₃), that the lift pin weight is formed from aluminum oxide (Al₂O₃), and that the cap member is formed from aluminum oxide (Al₂O₃).

In addition to one or more of the features described above, or as an alternative, further examples of the lift pin arrangement may include that the cap member has a cap member axial height, that the weight body has a weight body axial height, and that the cap member axial height is greater than the weight body axial height.

In addition to one or more of the features described above, or as an alternative, further examples of the lift pin arrangement may include that the cap member has a cap member interior width, that the weight body has a weight body width, and that the cap member interior width is greater than the weight body width. The cap member interior width may be equivalent to the weight body width.

A semiconductor processing system is provided. The semiconductor processing system includes a chamber body with an inlet port and an exhaust port, a showerhead, a substrate support, and a lift pin as described above. The showerhead is fixed within the chamber body between the inlet port and the exhaust port. The substrate support is arranged within the chamber body between the showerhead and the exhaust port. The substrate support further defines a lift pin aperture therein and the stem segment of the lift pin body is slidably received within the lift pin aperture.

In addition to one or more of the features described above, or as an alternative, further examples of the semiconductor processing system may include that the substrate support has a first position and a second position. The second position may separate the first position from the showerhead and a substrate support actuator may be operably connected to the substrate support to move the substrate support between the first position and the second position.

In addition to one or more of the features described above, or as an alternative, further examples of the semiconductor processing system may include a weight body with a recess receiving the neck segment of the lift pin body and a cap member. The cap member may have a stem segment aperture and a weight body aperture, the stem segment of the lift pin body may be slidably received within the stem segment aperture, and the weight body may be slidably received within the weight body aperture.

In addition to one or more of the features described above, or as an alternative, further examples of the semiconductor processing system may include that the recess has a first recess width and a second recess width, that the second recess width is axially offset from the first recess width, and that the first recess width is substantially equivalent to a stem segment width of the lift pin body. The second recess width defined by the weight body may be substantially equivalent to the neck segment width defined by the neck segment of the lift pin body.

A method making a lift pin arrangement for a semiconductor processing system is provided. The method includes, at a lift pin as described above, registering a cap member to the lift pin axis and translating the cap member in a first direction along the lift pin axis such that the stem segment of the lift pin body is slidably received in the cap member. A weight body is arranged along the lift pin axis, the weight body rotated such that a recess faces the neck segment of the lift pin body, and the weight body shifted relative to the lift pin body such that the neck segment of the lift pin body is slidably received within the recess. The cap member is then translated in a second direction along the lift pin body such that the cap member envelopes the weight body, the lift pin body thereby carrying the weight body.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a chamber arrangement in accordance with the present disclosure, showing a lift pin arrangement including a lift pin including a lift pin body and a weight body fixed to the lift pin by a cap member within the chamber arrangement;

FIG. 2 is schematic view of the chamber arrangement of FIG. 1 according to an example of the disclosure, showing the lift pin of the lift pin arrangement slidably received within a substrate support and the lift pin with a carried weight body dangling below the substrate support;

FIGS. 3-6 are schematic views of the chamber arrangement of FIG. 1 according to an example of the disclosure, sequentially showing the substrate support moving between a first position and a second position to seat and unseat a substrate using the lift pin arrangement;

FIG. 7 is an exploded view of the lift pin arrangement of FIG. 1 according to an example of the disclosure, showing the cap member and the weight body exploded away from the lift pin along a lift pin axis defined by the lift pin;

FIGS. 8 and 9 are side and perspective views of a base segment of the lift pin of included in the lift pin arrangement of FIG. 1 according to an example of the disclosure, showing a carrying face and a hemispherical face of the base segment of the lift pin, respectively;

FIGS. 10 and 11 are top plan and perspective views of the weight body included in the lift pin arrangement of FIG. 1 according to an example of the disclosure, showing a recess and a shoulder defined therein to axially fix the weight body to the lift pin body, respectively;

FIGS. 12 and 13 are top plan and perspective views of the cap member included in the lift pin arrangement of FIG. 1 according to an example of the disclosure, showing a stem segment aperture and a weight body aperture with a key portion axially therebetween, respectively;

FIG. 14 is perspective view of the lift pin arrangement of FIG. 1 according to an example of the disclosure, showing the weight body and the cap member being assembled onto the lift pin of the lift pin arrangement;

FIG. 15 is a cross-sectional side view of the lift pin arrangement and a portion of the semiconductor processing system of FIG. 1, showing the lift pin slidably received within the substrate support and lift pin weight dangling from the substrate support

FIG. 16 is cross-sectional side view of a portion of the lift pin arrangement of FIG. 1 according to an example of the present disclosure, showing a neck segment of the lift pin body and a key portion of the cap body received within the recess of the weight body;

FIG. 17 is a cross-sectional top view of the lift pin arrangement of FIG. 1 according to an example of the present disclosure; showing the key portion received within the recess defined within the weight body such that the weight body is fixed in rotation about the rotation axis relative to the cap member and free in rotation about the rotation axis relative to the lift pin; and

FIG. 18 is a block diagram of a method of making a lift pin arrangement for a semiconductor processing system according to the present disclosure, showing operations of the method according to a non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

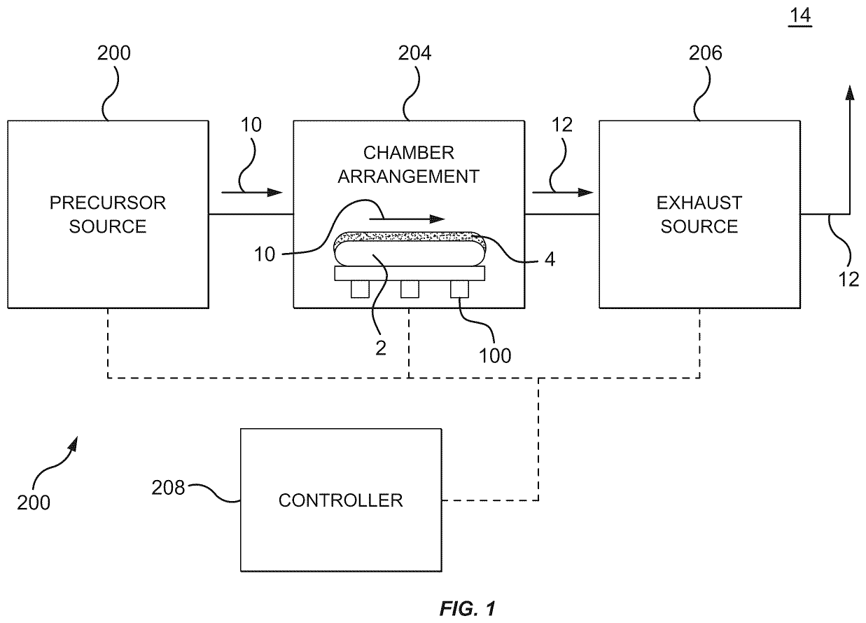

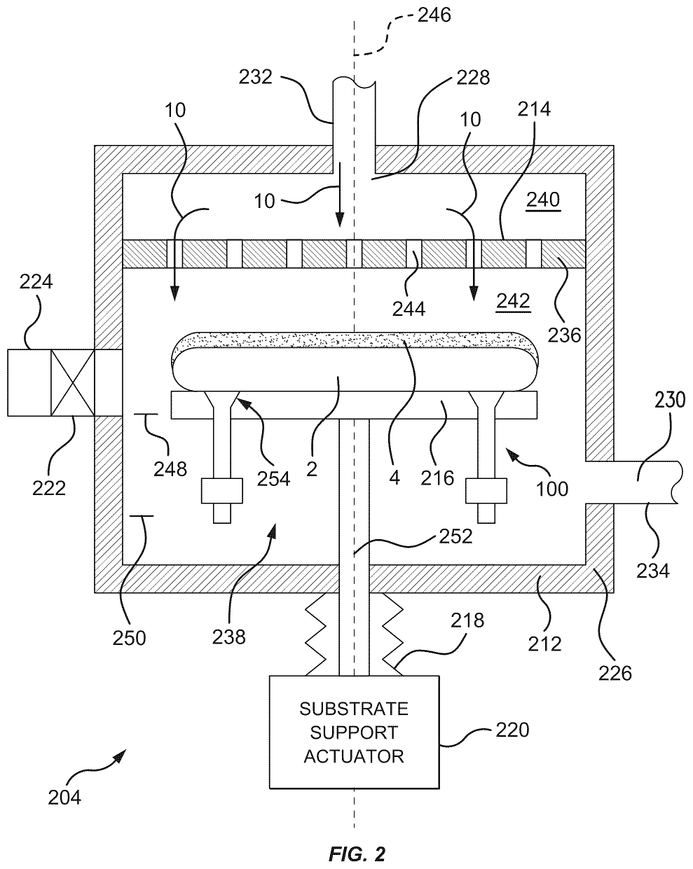

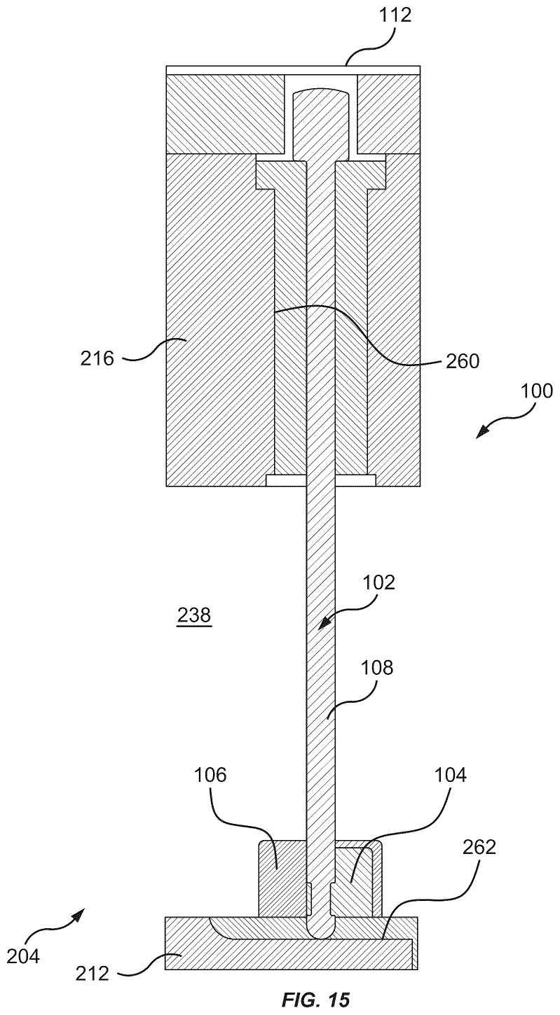

Reference will now be made to the drawings wherein like reference numerals identify similar structural features or aspects of the subject disclosure. For purposes of explanation and illustration, and not limitation, a partial view of a lift pin in accordance with the present disclosure is shown in FIG. 1 and is designated generally by reference character 100. Other examples of lift pins, lift pin arrangements and semiconductor processing systems including lift pin arrangements, and methods of making lift pin arrangements for semiconductor processing systems in accordance with the present disclosure, or aspects thereof, are provided in FIGS. 2-18, as will be described. The systems and methods of the present disclosure may be used for seating and unseating substrates within chamber arrangements having downflow architectures, such as in semiconductor processing system employed for depositing material layers using plasma enhanced chemical vapor deposition and atomic layer deposition techniques, though the present disclosure is not limited any particular chamber arrangement architecture or material layer deposition technique in general.

Referring to FIG. 1, a semiconductor processing system 200 is shown. The semiconductor processing system 200 generally includes a precursor source 202, a chamber arrangement 204, an exhaust source 206, and a controller 208. The precursor source 202 is configured to provide a flow of a material layer precursor 10 to the chamber arrangement 204. The chamber arrangement 204 is connected to the precursor source 202, includes the lift pin arrangement 100, and is configured to expose a substrate 2 to the material layer precursor 10 under environmental conditions that cause a material layer 4 to deposit onto the substrate 2. The exhaust source 206 is connected to the chamber arrangement 204 and is configured to communicate a flow of residual precursor and/or reaction products 12 to an external environment 14 outside of the semiconductor processing system 200. The controller 208 is operably connected to the semiconductor processing system 200, for example through a wired or wireless link 210, and is configured to control operation of the semiconductor processing system 200.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may an unpatterned, blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc.

With reference to FIG. 2, the chamber arrangement 204 is shown according to an example of the present disclosure. In the illustrated example the chamber arrangement 204 has a downflow architecture and in this respect includes a chamber body 212, a showerhead 214, a substrate support 216, and a bellows member 218. As shown and described herein the chamber arrangement 204 also includes a substrate support actuator 220, a gate valve 222, substrate transfer robot 224, and a lift pin arrangement 100. Although shown and described herein as including certain elements and having a specific arrangement (e.g., a downflow architecture), it is to be understood and appreciated that the chamber arrangement include additional elements and/or exclude certain elements shown and described herein, and/or have a different arrangement and remain within the scope of the present disclosure.

The chamber body 212 may be formed from a metallic material 226 and has an inlet port 228 and an exhaust port 230. The inlet port 228 is connected to the precursor source 202 (shown in FIG. 1) by a precursor supply conduit 232 and is configured to receive therethrough the flow of the material layer precursor 10. The exhaust port 230 is connected to the exhaust source 206 (shown in FIG. 1) by an exhaust conduit 234 and is configured to provide the flow of residual precursor and/or reaction products 12) issued by the chamber arrangement 204 during deposition of the material layer 4 onto the substrate 2 to the external environment 14 (shown in FIG. 1) outside the semiconductor processing system 200 (shown in FIG. 1). In certain examples, the metallic material 226 may include aluminum, such a low copper content aluminum alloy. In accordance with certain examples, the metallic material 226 may include a stainless-steel material, such as a low copper content stainless steel alloy.

The showerhead 214 is formed from a showerhead material 236, is fixed within an interior 238 of the chamber body 212 and separates the interior 238 of the chamber body 212 into a distribution plenum 240 and a process volume 242. The showerhead 214 further defines a plurality of flow apertures 244 therethrough, the plurality of flow apertures 244 fluidly coupling the distribution plenum 240 to the process volume 242, and thereby the inlet port 228 to the exhaust port 230, to provide the material layer precursor 10 to the substrate 2. In certain examples the showerhead material 236 may include aluminum, such a low copper content aluminum alloy. In accordance with certain examples, the showerhead material 236 may include a stainless-steel material, such as a low copper content stainless steel material.

The substrate support 216 is arranged within the interior 238 of the chamber body 212 along a drive axis 246 and is movable between a first position 248 and a second position 250. The first position 248 is proximate the showerhead 214, the second position 250 is axially separated from the showerhead 214 by the first position 248, and the substrate support actuator 220 is operably connected to the substrate support 216 to move the substrate support 216 between the first position 248 and the second position 250 along the drive axis 246. In this respect the substrate support actuator 220 may be coupled to the substrate support 216 by a pedestal member 252 extending into the interior 238 of the chamber body 212 and enclosed within the bellows member 218. If further respect, the substrate support actuator 220 may be operably associated with the controller 208 (shown in FIG. 1) to expose the substrate 2 to the material layer precursor 10 to deposit the material layer 4 onto the substrate 2 when in the first position 248, and to seat and unseat the substrate 2 from the substrate support 216 by translating the substrate support 216 along the drive axis 246 between the first position 248 and the second position 250 within the interior 238 of the chamber body 212.

The lift pin arrangement 100 is slidably received within the substrate support 216 and is movable therein between a retracted position 254, wherein the lift pin arrangement 100 is recessed within an upper surface 256 of the substrate support 216, and an extended position 258 (shown in FIG. A), wherein the lift pin arrangement 100 protrudes above the upper surface 256 of the substrate support 216. In this respect it is contemplated that the substrate support 216 define therein a plurality of lift pin apertures 260, that the lift pin arrangement 100 be one of a plurality of lift pin arrangements 100 included in the chamber arrangement 204, and that each of the plurality of lift pin apertures 260 slidably receive therein a respective one or the plurality of lift pin arrangements 100 to seat and unseat substrates, e.g., the substrate 2, from the substrate support 216. In the illustrated examples the substrate support 216 has three (3) lift pin apertures distributed circumferentially about the drive axis 246. This is for illustration and description purposes only and is non-limiting. As will be appreciated by those of skill in the art in view of the present disclosure, fewer or additional lift pin arrangements may be included in chamber arrangements and remain within the scope of the present disclosure.

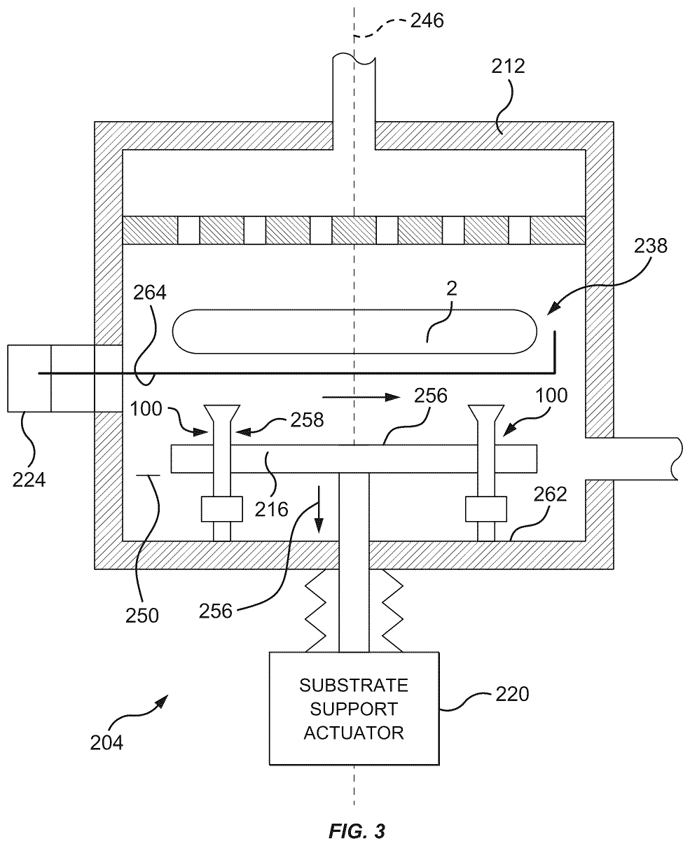

With reference to FIGS. 3-5, seating and unseating the substrate 2 on the substrate support 216 using the lift pin arrangement 100 is shown. As shown in FIG. 3, seating is accomplished by driving the substrate support 216 downwards within interior 238 of the chamber body 212 along the drive axis 246 using the substrate support actuator 220. Driving the substrate support 216 downwards within the chamber body 212 causes the lift pin arrangement 100 to engage (e.g., abut) an interior surface 262 of the chamber body 212, further downward translation 256 of the substrate support 216 toward the interior surface 262 of the chamber body 212 causing the lift pin arrangement 100 to protrude above the upper surface 256 of the substrate support 216 until such time that the substrate support 216 reaches the second position 250 and the lift pin arrangement 100 is in the extended position 258. Once the substrate support 216 reaches the second position 250, and the lift pin arrangement 100 protrudes above the upper surface 256 of the substrate support 216 in the extended position 258. The gate valve 222 may then be opened, an end effector carrying the substrate 2 advanced into the interior 238 of the chamber body 212, and the substrate 2 registered within the chamber body 212 to the substrate support 216.

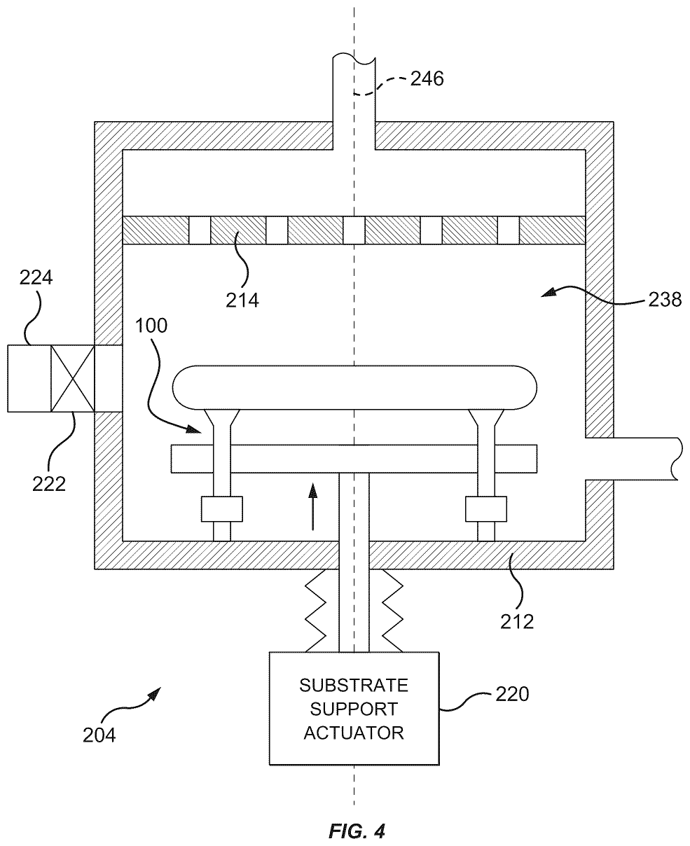

As shown in FIG. 4, once the substrate 2 is registered relative to the substrate support 216 the substrate 2 may be transferred to the lift pin arrangement 100 and the substrate supported on the lift pin arrangement 100. Transfer may be accomplished by a executing a downward stroke of the end effector 264 (shown in FIG. 3) using the substrate transfer robot 224. It is contemplated that the downward stroke transfer the substrate 2 to the lift pin arrangement 100, that the substrate transfer robot 224 thereafter withdraw the end effector 264 from the interior 238 of the chamber body 212, and that the gate valve 222 be closed. The substrate support actuator 220 thereafter drives the substrate support 216 upwards within the interior 238 of the chamber body 212 and along the drive axis 246 is a direction toward the showerhead 214.

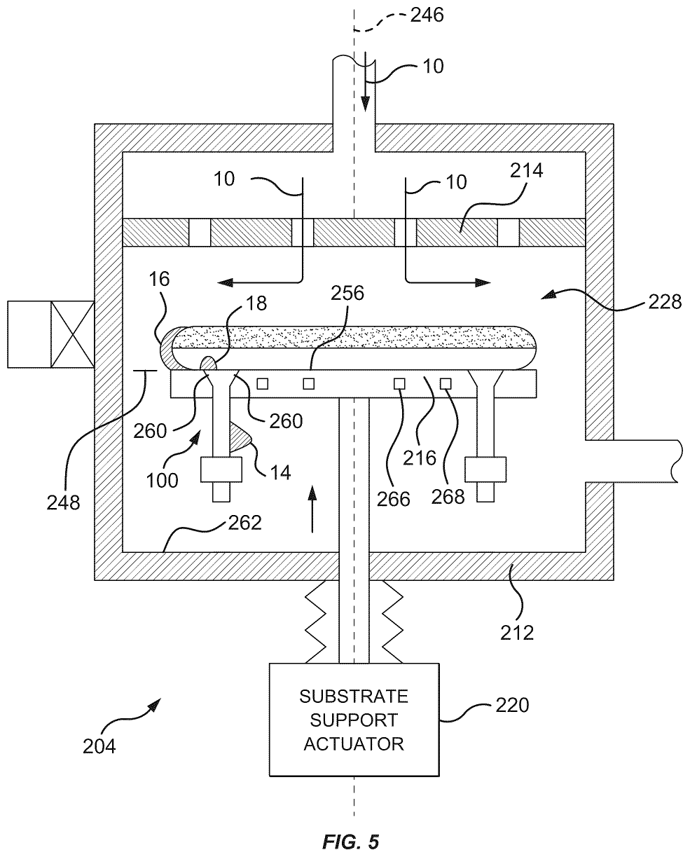

As shown in FIG. 5, seating the substrate 2 on the substrate support 216 is accomplished by driving the substrate support 216 upwards toward the showerhead 214 along the drive axis 246 using the substrate support actuator 220. Upward translation of the substrate support 216 along the drive axis 246 causes the lift pin arrangement 100 slide through substrate support 216 within the one of the plurality of lift pin apertures 260 slidably receiving the lift pin arrangement 100, the lift pin arrangement 100 seating in the upper surface 256 of the substrate support 216 as the substrate support 216 approaches the first position 248, the lift pin arrangement 100 dangling from the substrate support 216 and above the interior surface 262 of the chamber body 212 once the lift pin arrangement 100 is in the first position 248. The substrate 2 may then be exposed to a flow of the material layer precursor 10 received from the precursor source 202 (shown in FIG. 1) via the inlet port 228 and the showerhead 214, the substrate 2 heated to a predetermined material layer deposition temperature using one or more heater element 266 and/or a cooling circuit 268 arranged within the substrate support 216, and the material layer 4 deposited onto the substrate 2 using the flow of the material layer precursor 10.

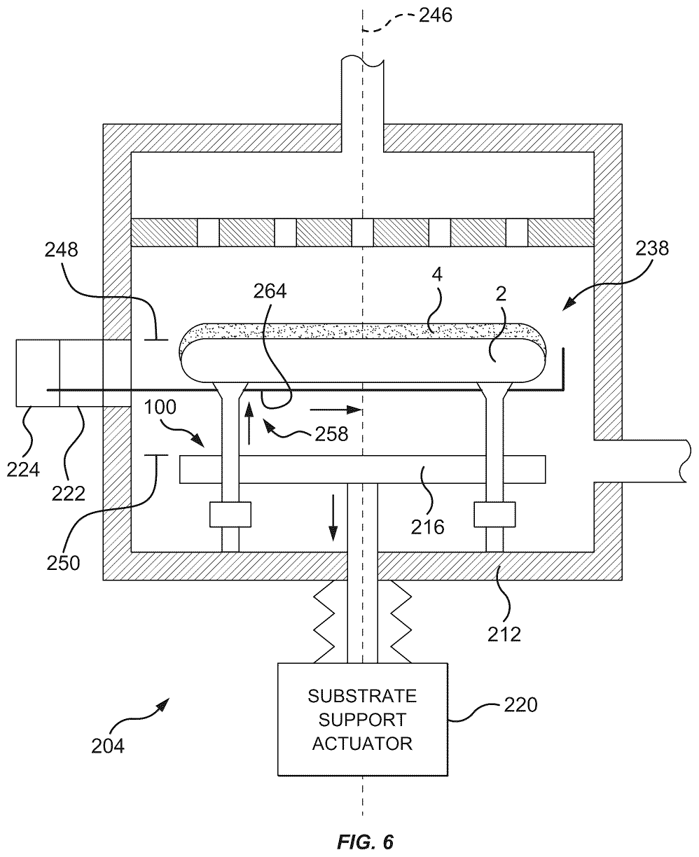

As shown in FIG. 6, once deposition of the material layer 4 is complete, the substrate 2 may be removed from the chamber body 212. Removal of the substrate 2 from the chamber body 212 may be accomplished by unseating the substrate 2 from the substrate support 216 by driving the substrate support 216 from the first position 248 to the second position 250 along the drive axis 246 using the substrate support actuator 220. Movement from the first position 248 to the second position 250 causes the lift pin arrangement 100 to engage (e.g., abut) the interior surface 262 of the chamber body 212, the lift pin arrangement 100 thereby sliding upwards through the substrate support 216 from the retracted position 254 (shown in FIG. 2) to the extended position 258. The gate valve 222 may then be opened, the end effector 264 again driven into the interior 238 of the chamber body 212 and positioned between the substrate 2 and the substrate support 216, and the substrate 2 transferred to the end effector 264 in an upward stroke, and the substrate 2 removed from the chamber body 212 by withdrawing the end effector 264 and the substrate 2 carried by the end effector 264 by operation of the substrate transfer robot 224 through the gate valve 222. As will be appreciated by those of skill in the art in view of the present disclosure, a substrate material layer may thereafter be deposited onto a subsequent substrate using the aforementioned operations, such as in a serial processing regime wherein material layers are sequentially deposited onto singular substrates successively using the flow of the material layer precursor 10 provided to the chamber arrangement 204 by the precursor source 202.

As has been explained above, material may, in some deposition operations, accrete on surfaces and structures located within the interior 238 of the chamber body 212, potentially reducing reliability of the semiconductor processing system 200 (shown in FIG. 1). For example, material 14 (shown in FIG. 5) may accrete on a stem portion of the lift pin slidably received within the one or the plurality of lift pin apertures 260 receiving the lift pin therein, potentially causing the lift pin to bind within the one of the plurality of lift pin apertures 260 during movement of the substrate support 216 between the first position 248 and the second position 250. Material 16 (shown in FIG. 5) may accrete on the upper surface 256 of the substrate support 216, potentially binding the lift pin therein and causing the lift pin to bind within the substrate support 216 during movement of the substrate support 216 between the first position 248 and the second position 250. And material 18 (shown in FIG. 5) may accrete between the substrate support 216 and a portion of the lift pin received within the substrate support 216, increasing resistance to sliding of the lift pin through the substrate support 216 and potentially causing the lift pin to bind within the one of the plurality of lift pin apertures 260 receiving the lift pin during movement between the first position 248 and the second position 250. To limit (or eliminate) risk of such lift pin binding, the lift pin arrangement 100 is provided.

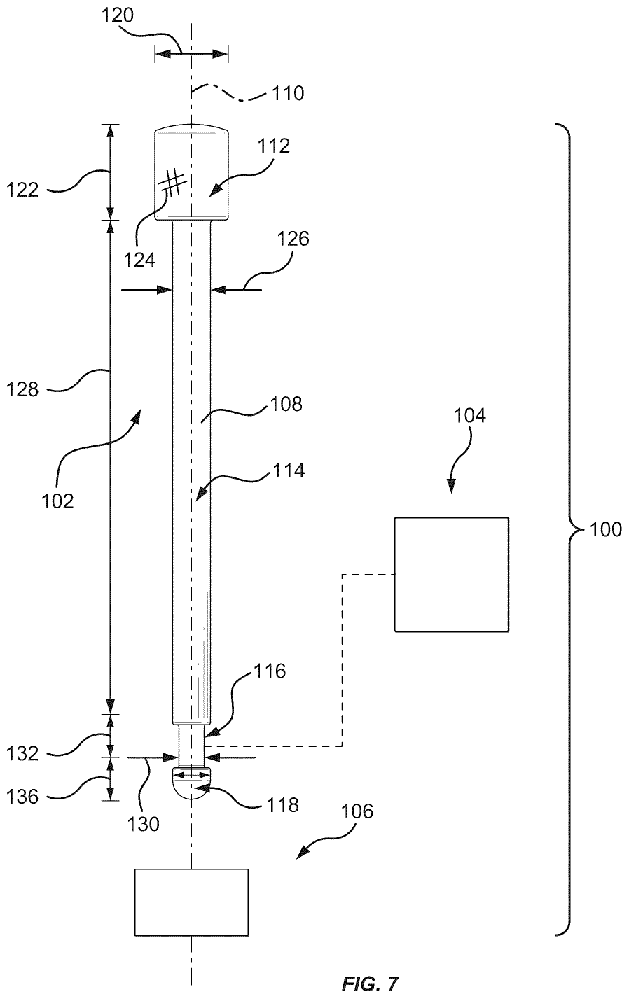

With reference to FIG. 7, the lift pin arrangement 100 is shown to an example of the present disclosure. In the illustrated example the lift pin arrangement 100 includes a lift pin 102, a weight body 104, and a cap member 106. The lift pin 102 is configured to carry the substrate 2 (shown in FIG. 1) and suspend the weight body 104 above the interior surface 262 (shown in FIG. 3) of the chamber body 212 (shown in FIG. 2) such that the mass of the weight body 104 opposes resistance to sliding movement of the lift pin 102 through the substrate support 216 (shown in FIG. 2), for example due accretion of material 14-18 (shown in FIG. 5). The weight body 104 is configured for fixation onto the lift pin 102, for example such that the weight body 104 is axially fixed relative a lift pin axis 110 defined by the lift pin 102 and radially free relative to lift pin axis 110 when seated onto the lift pin 102. The cap member 106 is configured to be slidably received onto the lift pin 102 such that the cap member 106 is axially free and radially fixed relative to the lift pin 102, the cap member 106 thereby radially fixing the weight body 104 relative to the lift pin axis 110 by capturing the weight body 104, the cap member 106 cooperating with the lift pin 102 to fix the weight body 104 to the lift pin 102 without fastening or threads.

The lift pin 102 includes a lift pin body 108. The lift pin body 108 defines (or is arranged along) the lift pin axis 110 and has a contact pad 112, a stem segment 114, a neck segment 116, and a base segment 118. The contact pad 112 is configured to carry the substrate 2 (shown in FIG. 1) during seating and unseating of the substrate 2 on the substrate support 216 (shown in FIG. 1) and in this respect may be radially enlarged relative to the other segments of the lift pin body 108, extends about lift pin axis 110, and has a contact pad width 120 and a contact pad height 122. In certain examples the contact pad 112 may have a cylindrical shape, the contact pad width 120 being a contact pad diameter in such examples. In certain examples the lift pin body 108 may be formed from a ceramic material 124. Examples of suitable ceramic materials include alumina, aluminum oxide (Al₂O₃), and silicon carbide (SiC). It is also contemplated that the lift pin body 108 may be formed from a carbonaceous material, such as glassy carbon by way of non-limiting example and remain within the scope of the present disclosure.

The stem segment 114 of the lift body 108 is configured to be slidably received within the substrate support 216 (shown in FIG. 1) and in this respect extends axially from the contact pad 112 along the lift pin axis 110. In further respect the stem segment 114 has a stem segment width 126 and a stem segment height 128. The stem segment width 126 is smaller than the contact pad width 120 of the contact pad 112. The stem segment height 128 is greater than the contact pad height 122 of the contact pad 112. The stem segment 114 may be cylindrical in shape, the stem segment 114 defining a circular cross-sectional area and the stem segment width 126 being a diameter in such examples. The stem segment 114 and the contact pad 112 may further define a fillet therebetween, the fillet reducing stress within the lift pin body 108.

The neck segment 116 of the lift pin body 108 is configured to fix the weight body 104 axially along the lift pin body 108 and in this respect extends axially from the stem segment 114 and is separated from the contact pad 112 by the stem segment 114 of the lift pin body 108. It is contemplated that the neck segment 116 have a neck segment width 130 and a neck segment height 132. The neck segment width 130 may be smaller than the stem segment width 126 of the stem segment 114. The neck segment height 132 may be smaller than the stem segment height 128. It is further contemplated that the neck segment height 132 may be smaller than the contact pad height 122 of the contact pad 112, and that the neck segment 116 may be cylindrical in shape. The neck segment 116 may define a circular cross-sectional area, the neck segment width 130 may be a diameter in such examples, and the neck segment 116 and the stem segment 114 may further define a fillet therebetween. As will be appreciated by those of skill in the art in view of the present disclosure, the fillet may further limit stress within the lift pin body 108, increasing mass that can be carried by the lift pin 102 relative to examples not having the fillet.

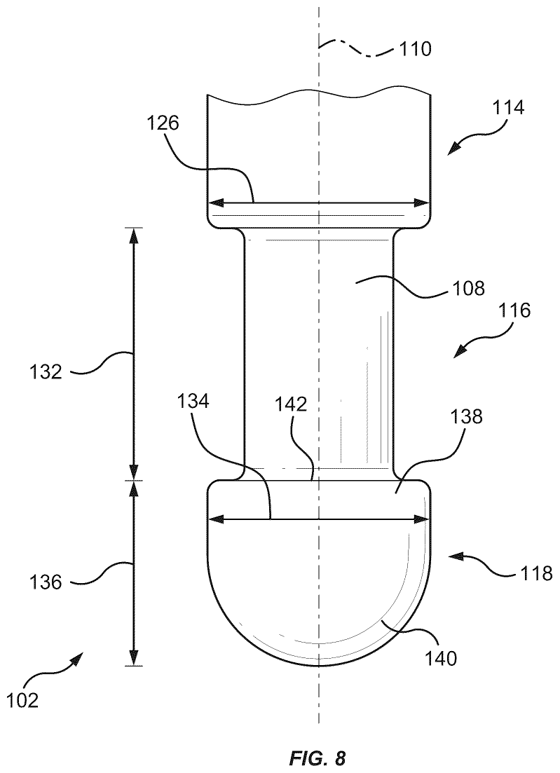

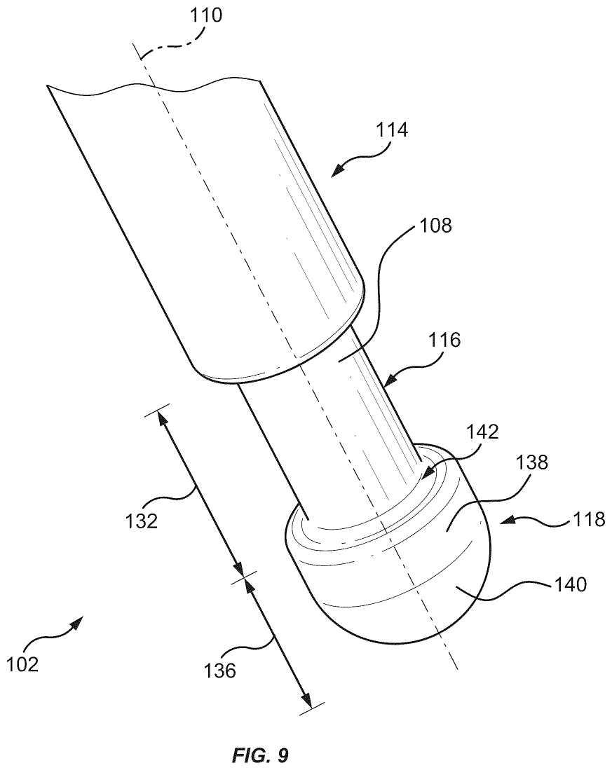

With reference to FIGS. 8 and 9, the base segment 118 of the lift pin body 108 is configured to seat the lift pin 102 the interior of the chamber body 212 (shown in FIG. 2). The base segment 118 of the lift pin body 108 is further configured to carry the weight body 104 (shown in FIG. 7), and thereby increase force that the lift pin body 108 may exert in response to sliding resistance of the lift pin 102 through the substrate support 216 (shown in FIG. 1). In these respects, the base segment 118 extends axially from the neck segment 116 and along the lift pin axis 110, is separated from the stem segment 114 of the lift pin body 108 by the neck segment 116 of the lift pin body 108 and has a base segment width 134 and a base segment height 136. The base segment width 134 may be greater than the neck segment width 130 of the neck segment 116 and may further be substantially equivalent to the stem segment width 126 of the stem segment 114. The base segment height 136 may be smaller than the neck segment height 132 of the neck segment 116, limiting size of the process volume 242 (shown in FIG. 2) necessary for cooperation of the weight body 104 with the lift pin body 108 with one another within the interior 238 of the chamber body 212. It is contemplated that the base segment 118 may have a cylindrical portion 138 and a hemispherical portion 140, the cylindrical portion 138 adjacent the neck segment 116 and defining the base segment width 134, the hemispherical portion 140 extending from the cylindrical portion 138 and separated from the neck segment 116 by the cylindrical portion 138 of the base segment 118. In certain examples the base segment 118 and the neck segment 116 may define a fillet therebetween, limiting stress within the lift pin body 108. In accordance with certain examples, the base segment 118 may join the neck segment 116 at an orthogonal interface, facilitating assembly of the weight body 104 onto the lift pin 102 and limiting slop within the lift pin arrangement 100.

In certain examples the base segment 118 may have an annular seating face 142. The annular seating face 142 is configured to slidably receive thereon the weight body 104 and in this respect extends circumferentially about the neck segment 116 of the lift pin body 108, opposes the stem segment 114 of the lift pin body 108, and is substantially orthogonal to the neck segment 116 of the lift pin body 108. It is contemplated that the annular seating face 142 extend circumferentially about the lift pin axis 110 and be substantially orthogonal relative to the lift pin axis 110. It is also contemplated that the hemispherical portion 140 of the base segment 118 define a pole 144 arranged along the lift pin axis 110 and axially spaced apart from the neck segment 116 by both the cylindrical portion 138 of the base segment 118 and the hemispherical portion 140 o the base segment 118 of the lift pin body 108.

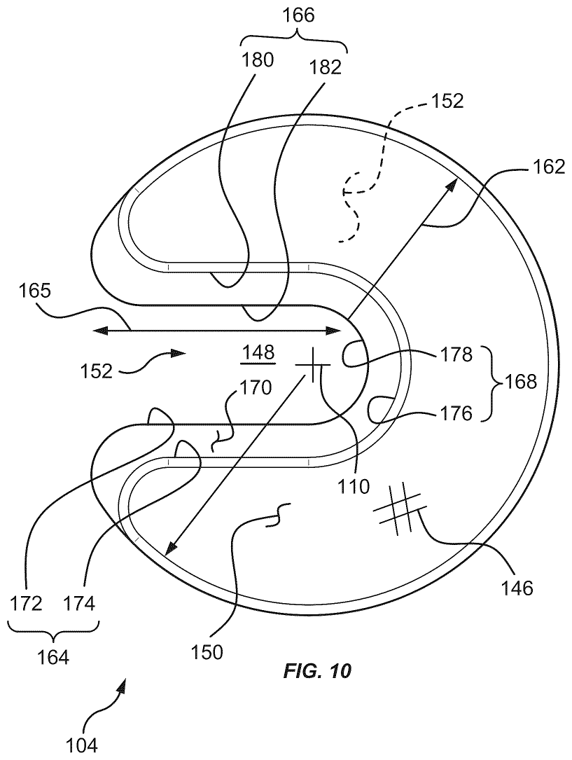

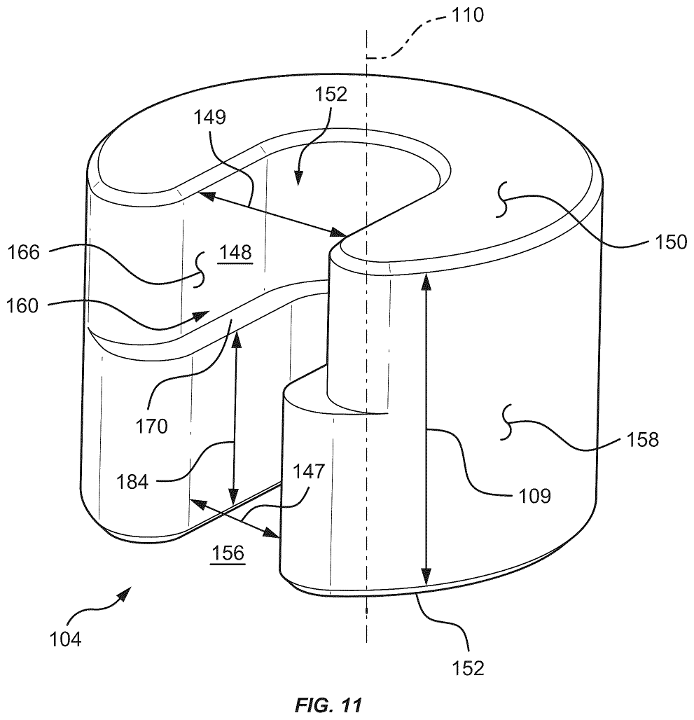

With reference to FIGS. 10 and 11, the weight body 104 is shown. As shown in FIG. 9, the weight body 104 is formed from a weight body material 146, is generally cylindrical in shape, and defines a recess 148. The weight body 104 further has a C-shaped upper surface 150 defining an upper surface opening 152 to the recess 148, a C-shaped lower surface 154 defining a lower surface opening 156 to the recess 148, and a lateral surface 158 with a lateral surface opening 160 to the recess 148. The C-shaped upper surface 150 may be substantially orthogonal relative the lift pin axis 110 when the weight body 104 is assembled onto the lift pin body 108 (shown in FIG. 7), extend circumferentially about the lift pin axis 110 in a generally circular shape interrupted by the recess 148, and define a weight body width 162 that may diametrically span both the weight body 104 and the recess 148. The C-shaped lower surface 154 is similar to the C-shaped upper surface 150, is axially offset from the C-shaped upper surface 150 of the weight body 104 along the lift pin axis 110 and is coupled to the C-shaped upper surface 150 by the lateral surface 158 of the weight body 104. In certain examples, the weight body material 146 may include a ceramic material, such as a bulk ceramic material. Examples of suitable ceramic materials include alumina, aluminum oxide (Al₂O₃), and silicon carbide (SiC) by way of non-limiting examples.

It is contemplated that the weight body 104 be configured to receive therein the lift pin body 108 (shown in FIG. 7). In this respect it is contemplated that the recess 148 may extend radially inward from the lateral surface opening 160, be bounded by a first interior planar facet 164, a second interior planar facet 166, and an interior cylindrical facet 168. The first interior planar facet 164 extends chordwise from the lateral surface opening 160 to the interior cylindrical facet 168. The interior cylindrical facet 168 opposes the lateral surface opening 160 along a diameter of the weight body 104, is separated from the lateral surface opening 160 of the recess 148 by the lift pin axis 110 and is spaced apart from the lateral surface opening 160 by a radially extending recess depth 165. It is contemplated that the recess depth 165 be greater than one-half the weight body width 162 defined by the weight body 104. For example, the recess depth 165 may be between about 60% and about 90% of the weight body width 162, or between about 60% and about 80% of the weight body width 162, or even between about 60% and about 70% of the weight body width 162. As will be appreciated by those of skill in the art in view of the present disclosure, recess depths within these ranges enable the weight body 104 to concentrically seat on the lift pin body 108 and about the lift pin axis 110.

In certain examples, the weight body 104 may be configured to receive both the neck segment 116 (shown in FIG. 7) and a portion of the stem segment 114 (shown in FIG. 7) of the lift pin body 108 (shown in FIG. 7). In this respect the recess 148 may further be bounded by an interior shoulder facet 170. The interior shoulder facet 170 may be substantially parallel to the C-shaped upper surface 150 and/or the C-shaped lower surface 154 of the weight body 104 and may be substantially orthogonal relative to the lift pin axis 110 when the weight body 104 is seated on the lift pin body 108. The interior shoulder facet 170 may extend from the lateral surface opening 160 radially inward into the weight body 104 to the interior cylindrical facet 168 and divide the first interior planar facet 164 into an upper first interior planar facet 172 and a lower first interior planar facet 174. The interior shoulder facet 170 may extend across the interior cylindrical facet 168 and divide the interior cylindrical facet 168 into an upper interior cylindrical facet 176 and a lower interior cylindrical facet 178. The interior shoulder facet 170 may extend across the second interior planar facet 166 and divide the second interior planar facet 166 into an upper second interior planar facet 180 and a lower second interior planar facet 182.

It is contemplated that the interior shoulder facet 170 be separated from the C-shaped lower surface 154 by a shoulder facet height 184. The shoulder facet height 184 may be substantially equivalent to the neck segment height 132 (shown in FIG. 7) of the lift pin body 108 (shown in FIG. 7), the interior shoulder facet 170 thereby dividing the recess 148 into a neck segment recess portion 186 and a stem segment recess portion 188. The neck segment recess portion 186 may be bounded by the lower first interior planar facet 174, the lower interior cylindrical facet 178, and the lower second interior planar facet 182, and thereby be configured to receive therein the entirety of the neck segment 116 (shown in FIG. 6) of the lift pin body 108. The stem segment recess portion 188 may be bounded by the upper first interior planar facet 172, the upper interior cylindrical facet 176, and the upper second interior planar facet 180, and thereby be configured to receive therein a portion of the stem segment 114 (shown in FIG. 6) of the lift pin body 108.

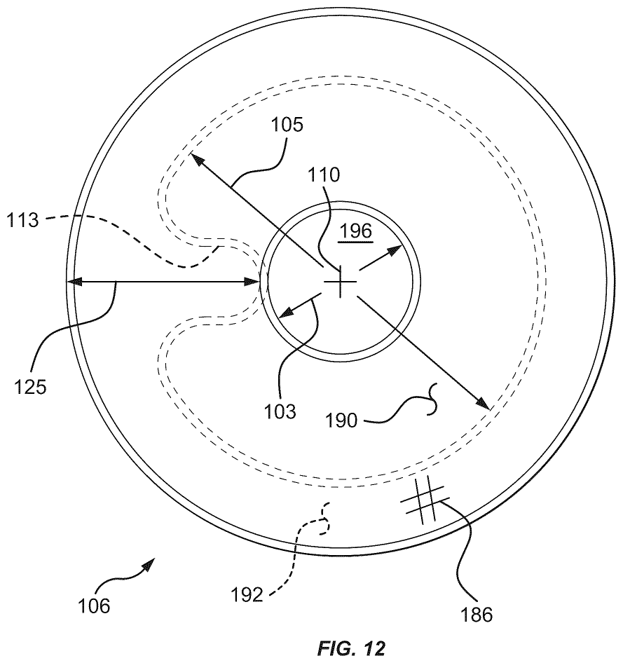

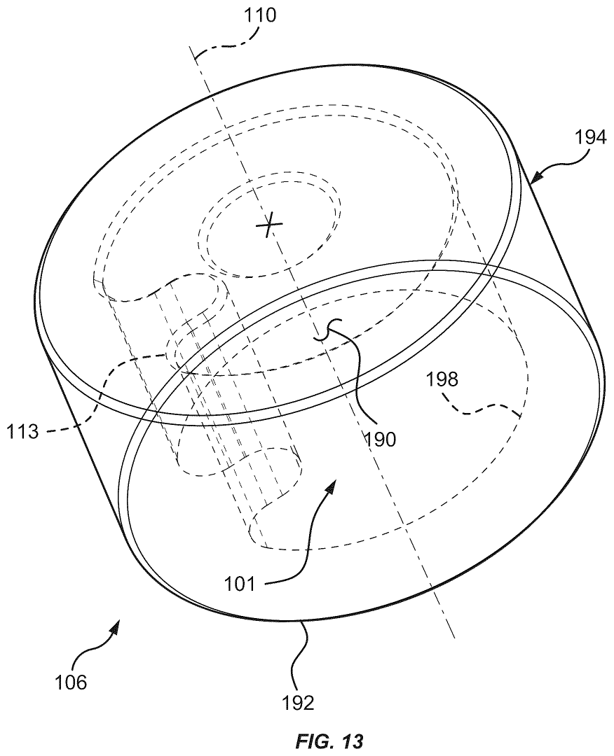

In certain examples the neck segment recess portion 186 may define a first recess width 147 between the lower first interior planar facet 174 and the lower second interior planar facet 182 and the stem segment recess portion 188 may define a second recess width 149 between the upper first interior planar facet 172 and the upper second interior planar facet 180. The first recess width 147 may be substantially equivalent to the neck segment width 130 and the second recess width 1491 may be substantially equivalent to the stem segment width 126. As will be appreciated by those of skill in the art in view of the present disclosure, the interior shoulder facet 170 and the C-shaped lower surface 154 may cooperate with the neck segment 116 of the lift pin body 108 to axially fix the weight body 104 relative to the lift pin body 108 when the neck segment 116 is received within the recess 148. With reference to FIGS. 12 and 13, the cap member 106 is shown. The cap member 106 is formed from a cap member material 186 and has an annular upper surface 190, an annular lower surface 192, and an annular cap member body 194. The annular upper surface 190 extends circumferentially about a stem aperture 196. The annular lower surface 192 extends circumferentially about a weight body aperture 198. The annular cap member body 194 extends circumferentially about a hollow interior 101 of the cap member 106, the hollow interior 101 coupling the stem aperture 196 defined by the annular upper surface 190 to the weight body aperture 198 of the annular lower surface 192 of the cap member 106. In certain examples the cap member material 186 forming the cap member 106 may include a ceramic material, such as a bulk ceramic material. Examples of suitable ceramic materials include alumina, aluminum oxide (Al₂O₃), and silicon carbide (SiC) by way of non-limiting examples.

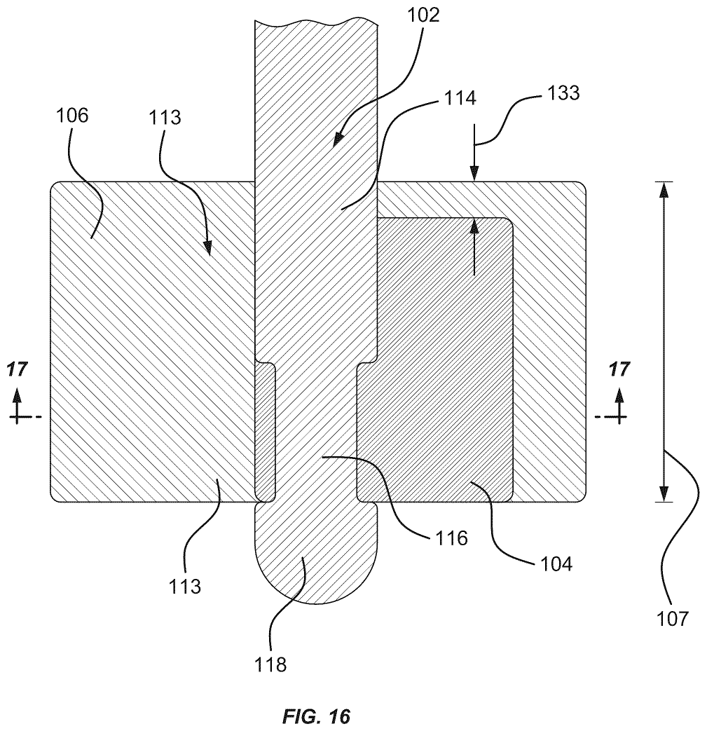

It is contemplated that the cap member 106 be configured to slidably receive therein both the lift pin body 108 (shown and FIG. 7) and the weight body 104 (shown in FIG. 7). In this respect the stem aperture 196 may have a stem aperture width 103 that is substantially equivalent to the stem segment width 126 (shown in FIG. 7) of the stem segment 114 (shown in FIG. 7) and may have a shape substantially identical to that of the cross-sectional area of the stem segment 114 of the lift pin body 108. In further respect, the weight body aperture 198 may have weight body aperture width 105 that is substantially equivalent to the weight body width 162 (shown in FIG. 10), and annular cap member body 194 may have cap member interior height 107 (shown in FIG. 16) that is substantially equivalent to a weight body height 109 (shown in FIG. 11) of the weight body 104. As will be appreciated by those of skill in the art in view of the present disclosure, sizing the stem aperture width 103 to be substantially equivalent to the stem segment width 126 and of substantially identical shape enables the cap member 106 to slidably receive therethrough the stem segment 114 of the lift pin body 108. As will also be appreciated by those of skill in the art in view of the present disclosure, sizing the weight body aperture width 105 to be substantially equivalent to the weight body width 162, and the cap member interior height 107 to be substantially equivalent to the weight body height 109, enables the cap member 106 to capture and thereby radially fix the weight body 104 about the lift pin body 108 during assembly of the lift pin arrangement 100 (shown in FIG. 1).

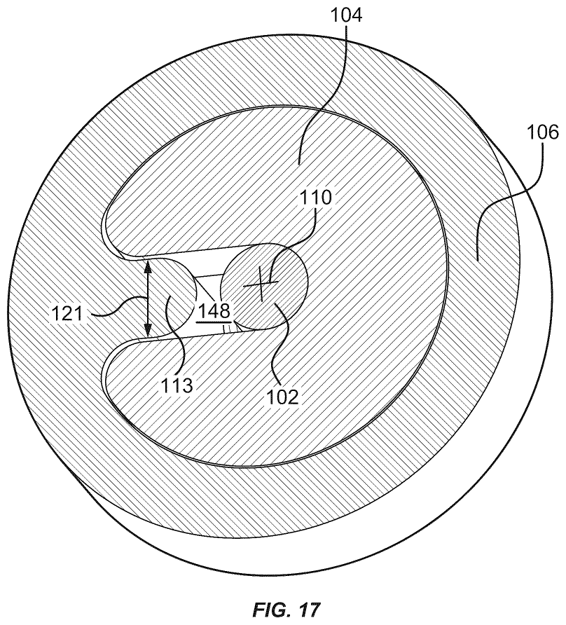

It is also contemplated that the cap member 106 define a key portion 113. The key portion 113 may be configured to fix the cap member 106 in rotation relative to the weight body 104 (shown in FIG. 7) about the lift pin axis 110 when the cap member 106 and the weight body 104 are assembled onto the lift pin body 108. In this respect the key portion 113 may protrude radially into the hollow interior 101 of the cap member 106 from a cap member interior surface 119 bounding the hollow interior 101 of the cap member 106. The key portion 113 may have a key portion width 121 (shown in FIG. 17), which may be substantially equivalent to the recess width 147 (shown in FIG. 11) defined between the lower first interior planar facet 174 (shown in FIG. 11) and the lower second interior planar facet 182 (shown in FIG. 11) of the recess 148 (shown in FIG. 10) defined within the weight body 104. In further respect, the key portion 113 may have a radial extent 125 that is less than one-half the weight body width 162, enabling the key portion 113 of the cap member 106 to abut the neck segment 116 of the lift pin body 108 when the weight body 104 is captive within the cap member 106. In certain examples, the key portion 113 may be substantially planar along the cap member interior height 107, the key portion 113 spaced apart from at least one of the upper first interior planar facet 172 and the upper second interior planar facet 180 to simplify fabrication of the cap member 106. In accordance with certain examples, the cap member 106 and the weight body 104 rotationally fixed to one another and collectively free in rotation relative to the lift pin body 108 about the lift pin axis 110. As will be appreciated by those of skill in the art in view of the present disclosure, this can simplify maintenance of the chamber arrangement 204 (shown in FIG. 1), for example by providing a maintainer tactile indication (e.g., a gross reality check-type manual inspection) of whether accrete material inhabits mechanical clearances within the lift pin arrangement 100 (shown in FIG. 1), potentially bringing risk of contamination during operation of the semiconductor processing system 200 (shown in FIG. 1).

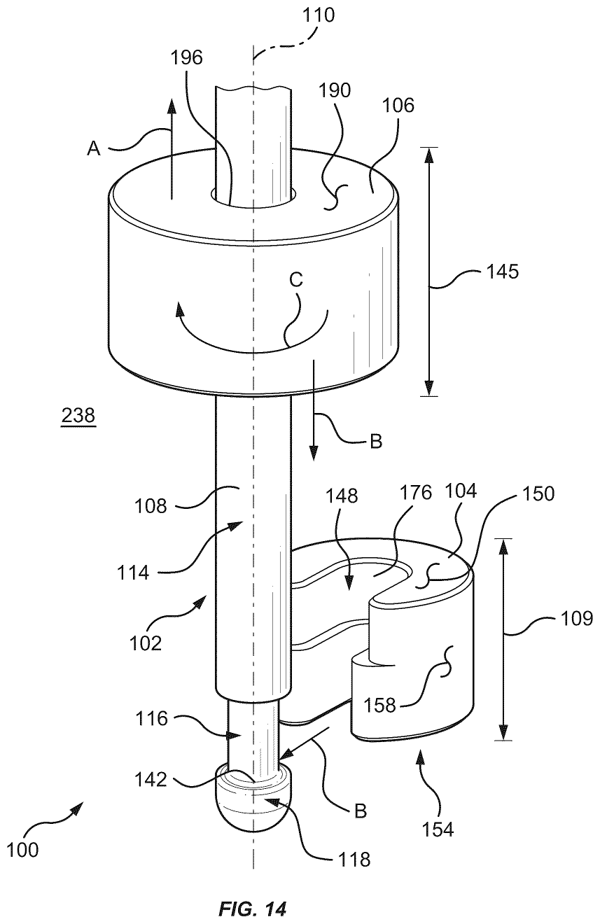

It is contemplated that the cap member 106 have a cap member axial height 145 (shown in FIG. 14), that the weight body 104 have a weight body axial height 109 (shown in FIG. 11), and that the cap member axial height 145 be greater than the weight body axial height 109. For example, the cap member axial height 127 may be greater than or equal the weight body axial height 109 plus an axial thickness 133 of the annular upper surface 190 of the cap member 106. As will be appreciated by those of skill in the art in view of the present disclosure, this enables the cap member 106 to envelope the weight body 104 when both the weight body 104 and the cap member 106 are assembled onto the lift pin body 108. It is also contemplated that the cap member 106 may have a cap member interior width 137, and that the cap member interior width 137 may be substantially equivalent to the substantially equivalent to the weight body width 143. As will also be appreciated by those of skill in the art in view of the present disclosure, this fixed the cap member 106 in tilt relative to the lift pin axis 110 through the weight body 104.

With reference to FIGS. 14-17, assembly of the lift pin arrangement 100 and arrangement of the lift pin arrangement 100 following assembly are shown. As shown in FIG. 14, assembly of the lift pin arrangement 100 is accomplished seating the lift pin 102 in the one of the plurality of lift pin apertures 260 (shown in FIG. 2) defined within the substrate support 216 such that a portion of the stem segment 114, the neck segment 116, and the base segment 118 each dangle below the substrate support 216 (shown in FIG. 2) and within the interior 238 (shown in FIG. 2) of the chamber body 212 (shown in FIG. 2). Next, the cap member 106 is registered to the lift pin body 108 in-situ (e.g., within the chamber body 212) such that the base segment 118 of the lift pin body 108 is axially between the cap member 106 and the neck segment 116 of the lift pin body 108, and the stem aperture 196 defined within the annular upper surface 190 of the cap member 106 and the lift pin body 108 are coaxial with one another. The cap member 106 is thereafter translated along the lift pin axis 110 in a first direction A toward the contact pad 112 of the lift pin body 108, the stem segment 114 of the lift pin body 108 thereby being slidably received within the stem aperture 196 of the cap member 106. It is contemplated that the cap member 106 be translated along the lift pin axis 110 such that the annular lower surface 192 of the cap member 106 axially overlaps the stem segment 114 of the lift pin body 108, clearing an axial length of the lift pin body 108 inhabited by the weight body 104 when assembled onto the lift pin body 108.

Assembly of the weight body 104 onto the lift pin body 108 is accomplished by registering the weight body 104 relative to the lift pin body 108 axially such that the recess 148 of the weight body 104 opposes the neck segment 116 of the lift pin body 108, and that the C-shaped lower surface 154 is axially aligned with the annular seating face 142 of the base segment 118 of the lift pin body 108. So registered, the weight body 104 may then be shifted B (e.g., advanced radially) toward the lift pin body 108 such that the C-shaped lower surface 154 slides across the annular seating face 142 of the base segment 118 of the lift pin body 108. It is contemplated that the C-shaped lower surface 154 slide across the annular seating face 142 of the base segment 118 until the lower interior cylindrical facet 178 (shown in FIG. 10) abuts the neck segment 116 of the lift pin body 108, and the upper interior cylindrical facet 176 abuts a lower extent (e.g., lower portion) of the stem segment 114. As will be appreciated by those of skill in the art in view of the present disclosure, so positioned, the weight body 104 is axially fixed relative to the lift pin body 108 along the neck segment 116 by cooperation of the base segment 118 and the stem segment 114 of the lift pin body 108.

Once the weight body 104 is seated on the annular seating face 142 of the base segment 118 of the lift pin body 108 and about the stem segment 114, the cap member 106 may then be rotated D about the lift pin body 108 relative to the weight body 104, or vice versa, such that the key portion 113 (shown in FIG. 12) of the cap member 106 axially overlays the recess 148 defined by within the lateral surface 158 of the weight body 104. The cap member 106 may then be translated along the lift pin axis 110 in a second direction B opposite the first direction A (e.g., in a direction opposite the contact pad 112 and toward the base segment 118), the key portion 113 of the cap member 106 thereby being received within the recess 148 defined within the lateral surface 158 of the weight body 104. It is contemplated that the cap member 106 be further translated along the lift pin body 108 such that the annular upper surface 190 of the cap member 106 comes into abutment with the C-shaped upper surface 150 of the weight body 104. As will be appreciated by those of skill in the art in view of the present disclosure, this radially fixes the weight body 104 within the cap member 106 relative the lift pin body 108, the weight body 104 and the cap member 106 thereby loading the lift pin body 108 axially in tension when the lift pin body 108 dangles from the substrate support 216 within the interior 238 (shown in FIG. 2) of the chamber body 212 (shown in FIG. 2). As will also be appreciated by those of skill in the art in view of the present disclosure, once assembled, the lift pin arrangement 100 increases force exerted on the lift pin body 108 during sliding through the one of the plurality of lift pin apertures 260 (shown in FIG. 2) slidably receiving the lift pin body 108 and/or during upward movement of the substrate support 216 (shown in FIG. 2) within the chamber body 212, limiting (or eliminating) risk that accreted material cause the lift pin 102 to bind within the substrate support 216. Advantageously, in certain examples described herein, assembly of the lift pin arrangement 100 may be accomplished within fasteners and tools, simplifying assembly and/or maintenance of the chamber arrangement 204 and thereby the semiconductor processing system 200 including the lift pin arrangement 100.

In certain examples, the lift pin arrangement 100 may have a lift pin arrangement center of gravity 131 (shown in FIG. 17) that is offset from the lift pin axis 110. In this respect it is contemplated that the (a) the lift pin body 108 have a lift pin body center of gravity 135 (shown in FIG. 17) that is on-center, i.e., lies along the lift pin axis 110, (b) that the weight body 104 have a weight body center of gravity 139 (shown in FIG. 17) that is radially offset from the lift pin axis 110, and (c) that the cap member 106 have a cap member center of gravity 141 (shown in FIG. 17) is radially offset from the lift pin axis 110 in a direction diametrically opposite the weight body center of gravity 139. It is contemplated that the volume and composition of the weight body 104 and the cap member 106 be such that the weight body center of gravity 139 and the cap member center of gravity 141 cooperate to position the lift pin arrangement center of gravity 131 on a side of the lift pin axis 110 opposite the key portion 113. Advantageously, the lift pin arrangement center of gravity 131 may induce an off-axis force component into the lift pin arrangement 100 during movement of the substrate support 216 between the first position 248 (shown in FIG. 2) and the second position 250 (shown in FIG. 2), promoting yaw into the lift pin arrangement 100 and promoting fracture in accreted material that may be resident within clearances between the lift pin arrangement and the substrate support 216. As will be appreciated by those of skill in the art in view of the present disclosure, this can further limit the tendency of such accreted material to cause the lift pin arrangement 100 to bind within the substrate support 216.

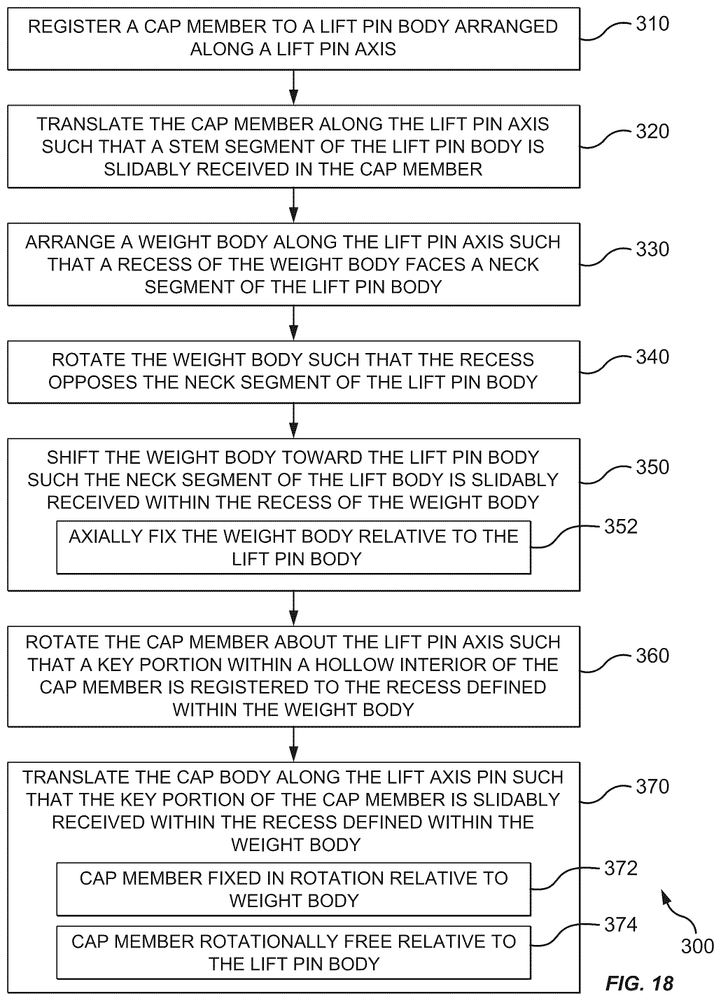

With reference to FIG. 18, a method 300 of making a lift pin arrangement, e.g., the lift pin arrangement 100 (shown in FIG. 1), is shown. The method 300 includes, at a lift pin, e.g., the lift pin 102 (shown in FIG. 6), registering a cap member to the a lift pin body along a lift pin axis, e.g., the cap member 106 (shown in FIG. 6) to the lift pin body 108 (shown in FIG. 6) along the lift pin axis 110 (shown in FIG. 6), as shown with box 310. The cap member is then translated along the lift pin axis such that a stem segment of the lift pin body is slidably received in the cap member, e.g., the stem segment 114 (shown in FIG. 6) slidably receive within the stem aperture 196 (shown in FIG. A) of the cap member, as shown with box 320. A weight body is then arranged along the lift pin axis, e.g., the weight body 104 (shown in FIG. 6), and the weight body rotated such that a recess of the weight body and a neck segment of the lift pin body inhabit a common axial position along the lift pin axis, e.g., the weight body rotated such that the recess 148 (shown in FIG. A) faces (opposes) the neck segment 116 (shown in FIG. 6) of the lift pin body, as shown with box 330 and box 340.

Next, the weight body is assembled onto the lift pin body by shifting the weight body toward the lift pin body (e.g., driven radially toward the lift pin body) such that the neck segment of the lift pin body is slidably received within the recess of the weight body, as shown with box 350. The cap member is then rotated about the lift pin body such that a key portion extending radially inward from an interior surface of the cap member axially overlaps the recess of the weight body, e.g., the key portion 113 (shown in FIG. A) extending radially inward from the cap member interior surface 119 (shown in FIG. A) into the hollow interior 101 (shown in FIG. A) axially overlaps the recess defined within the lateral surface of the weight body, as shown with box 360. The cap member is then translated in a second direction axially opposite the first direction along the lift pin body such that cap member substantially envelopes the weight body, as shown with box 370. It is contemplated that translating 320 the cap body along the lift pin body radially in the first direction fix the cap member relative to the lift pin body while leaving the cap axially free relative to the lift pin body, as shown with box 372. It is further contemplated that translating the cap member in the second direction relative to the lift pin body axially constrain the cap member and radially fix the weight body relative to the lift pin body, as shown with box 374.

Substrates may be seated on substrate supports using lift pins, such as prior to deposition of material layers onto substrates using plasma enhanced chemical vapor deposition and plasma enhanced atomic layer deposition techniques. Although generally satisfactory for their intended purpose, material may accrete, in some deposition techniques, onto the lift pins and/or within mechanical clearances defined between the lift pins and the substrate support, potentially limiting reliability of the semiconductor processing system employed for the material layer deposition operation. And while various countermeasures exist for limiting such material layer accretion, such as through temperature control and/or removal of the accreted material between material layer deposition events, there remains a need for improved lift pins, lift pin arrangements and semiconductor processing systems including lift pin arrangements, and methods of making lift pin arrangements for semiconductor processing systems.

In examples described herein, lift pin arrangements are provided including weight bodies carried by the lift, increasing force that the lift pin may exert against resistance to sliding within the substrate support slidably receiving the lift pin. In certain examples the lift pin arrangement may include a cap member to fix the weight body carried by the lift pin relative to the lift pin, limiting (or eliminating) the need for fasteners and/or tools to assembly the lift pin arrangement, simplifying assembly of the lift pin arrangement. In accordance with certain examples, the lift pin weight and cap member may be rotationally fixed relative to one another and rotationally free relative to the lift pin, providing tactile indication of material layer accretion within the lift pin arrangement, simplifying inspection and maintenance of the lift pin arrangement. It is also contemplated that the cap member may shift the center of gravity of the lift pin arrangement off the lift pin axis of the lift pin member, promoting yaw of the lift pin within the lift pin aperture and promoting fracture of accreted material at the beginning of sliding of the lift pin arrangement during unseating the substrate subsequent to material layer deposition on the substrate seated on the substrate support.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A lift pin, comprising:
a lift pin body arranged along a lift pin axis, the lift pin body having:
an enlarged contact pad;
a stem segment extending axially from the contact pad;
a neck segment extending axially from the stem segment and separated from the contact pad by the stem segment of the lift pin body; and
a base segment extending axially from the neck segment and separated from the stem segment by the neck segment,
wherein the base segment has a base segment width, wherein the neck segment has a neck segment width, and wherein the neck segment width is smaller than the base segment width to carry a lift pin weight with the lift pin body.

2. The lift pin of claim 1, wherein the lift pin body is formed from a ceramic material.

3. The lift pin of claim 1, wherein the contact pad has a contact pad width, wherein the stem segment has a stem segment width, and the wherein the stem segment width is smaller than the contact pad width and greater than the neck segment width.

4. The lift pin of claim 1, wherein the base segment has an annular seating face and a hemispherical portion, wherein the annular seating face extends about the neck segment and opposes the stem segment of the lift pin body, and wherein the annular seating face is orthogonal relative to the lift pin axis.

5. The lift pin of claim 1, wherein the base segment has base segment height, wherein the neck segment has a neck segment height that is greater than the base segment height, wherein the contact pad has a contact pad height that is greater than the neck segment height, and wherein the stem segment has a stem segment height that is greater than the contact pad height.

6. A lift pin arrangement, comprising:
a lift pin as recited in claim 1;
a weight body seated on the base segment of the lift pin body, the weight body axially fixed and radially free relative to the lift pin body; and
a cap member slidably received on the lift pin body and extending circumferentially about the weight body, wherein the cap member is axially free and radially fixed relative to the lift pin body.

7. The lift pin arrangement of claim 6, wherein the lift pin body has a lift pin body center of gravity arranged along the lift pin axis, wherein the weight body has a weight body center of gravity that is radially offset from the lift pin axis, and wherein the cap member has a cap member center of gravity that is radially offset from the lift pin axis, and wherein the lift pin arrangement has a lift pin arrangement center of gravity that is offset from the lift pin axis.

8. The lift pin arrangement of claim 6, wherein the weight body has a weight body width and a recess, and wherein the recess has a recess depth that spans more than one-half of the weight body width.

9. The lift pin arrangement of claim 8, wherein the weight body defines an interior shoulder facet that is substantially orthogonal relative to the lift pin axis, the weight body having a C-shaped upper surface and a C-shaped lower surface axially opposite the C-shaped upper surface and is parallel with the interior shoulder facet, the interior shoulder facet axially spaced from the base segment of the lift pin body by a neck segment height of the neck segment.

10. The lift pin arrangement of claim 8, wherein the cap member has an axially extending key portion slidably received within the recess of the weight body.

11. The lift pin arrangement of claim 6, wherein the recess has a recess width, and wherein the neck segment width is substantially equivalent to the recess width.

12. The lift pin arrangement of claim 6, wherein the cap member has an annular upper surface and an annular lower surface, the annular upper surface extending circumferentially about the stem segment of the lift pin body and radially fixing the cap member relative to the lift pin body, the annular lower surface extending about the weight body and radially fixing the weight body relative to the cap member.

13. The lift pin arrangement of claim 6, wherein the lift pin body is formed from aluminum oxide (Al₂O₃), wherein the lift pin weight is formed from aluminum oxide (Al₂O₃), and wherein the cap member is formed from aluminum oxide (Al₂O₃).

14. The lift pin arrangement of claim 6, wherein the cap member has a cap member axial height, wherein the weight body has a weight body axial height, and wherein the cap member axial height is greater than the weight body axial height.

15. The lift pin arrangement of claim 6, wherein the cap member has a cap member interior width, wherein the weight body has a weight body width, wherein the cap member interior width is greater than the weight body width, and wherein the cap member interior width is equivalent to the weight body width.

16. A semiconductor processing system, comprising:
a chamber body with an inlet port and an exhaust port;
a showerhead fixed within the chamber body between the inlet port and the exhaust port;
a substrate support arranged within the chamber body between the showerhead and the exhaust port, the substrate support defining a lift pin aperture therein; and
a lift pin as recited in claim 1, wherein the stem segment of the lift pin body is slidably received within the lift pin aperture.

17. The semiconductor processing system of claim 16, wherein the substrate support has a first position and a second position separating the first position from the showerhead, the semiconductor processing system further comprising a substrate support actuator operably connected to the substrate support to move the substrate support between the first position and the second position.

18. The semiconductor processing system of claim 16, further comprising:
a weight body with a recess receiving the neck segment of the lift pin body; and
a cap member with a stem segment aperture and a weight body aperture, the stem segment of the lift pin body slidably received within the stem segment aperture, the weight body slidably received within the weight body aperture.

19. The semiconductor processing system of claim 18, wherein the recess has a first recess width and a second recess width, wherein the second recess width is axially offset from the first recess width, wherein the first recess width is substantially equivalent to a stem segment width of the lift pin body, and wherein the second recess width is substantially equivalent to the neck segment width defined by the neck segment of the lift pin body.

20. A method of making a lift pin arrangement for a semiconductor processing system, the method comprising:
at a lift pin including a lift pin body arranged along a lift pin axis having an enlarged contact pad, a stem segment extending axially from the contact pad, a neck segment extending axially from the stem segment and separated from the contact pad by the stem segment of the lift pin body, and a base segment extending axially from the neck segment and separated from the stem segment by the neck segment, the base segment having a base segment width, the neck segment having a neck segment width, the neck segment width smaller than the base segment width,
registering a cap member to the lift pin axis;
translating the cap member in a first direction along the lift pin axis such that the stem segment of the lift pin body is slidably received in the cap member;
arranging a weight body along the lift pin axis;
rotating the weight body such that a recess faces the neck segment of the lift pin body;
shifting the weight body relative to the lift pin body such that the neck segment of the lift pin body is slidably received within the recess; and
translating the cap member in a second direction along the lift pin body such that the cap member envelopes the weight body, whereby the lift pin body carries the weight body.
